(19) United States
(12) Patent Application Publication
(10) Pub. No.: US 2005/0095801 A1
(43) Pub. Date: May 5, 2005

(54) Trench capacitor and method of manufacturing the same

(76) Inventors: Mitsuru Sato, Yokkaichi-shi (JP); Hirofumi Inoue, Yokkaichi-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/947,388

(22) Filed: Sep. 23, 2004

(30) Foreign Application Priority Data
Sep. 25, 2003 (JP) 2003-334105

(51) Int. Cl. H01L 21/8242; H01L 27/108; H01L 29/76; H01L 29/94; H01L 31/119; H01L 21/20

(52) U.S. Cl. 438/390; 257/301

(57) ABSTRACT

A trench capacitor comprises a semiconductor substrate, a trench provided in the semiconductor substrate, a first doped polysilicon filled in the trench at a lower end of the trench via a first dielectric film, and a second doped polysilicon filled in the trench at an upper end of the trench via a second dielectric film, the second doped polysilicon being contiguously disposed to the first doped polycrystal silicon, wherein the second dielectric film consists of an oxide film using radicals.

### CROSS-REFERENCE TO RELATED APPLICATIONS

This application is based upon and claims the benefit of priority from prior Japanese Patent Application No. 2003-334105, filed Sep. 25, 2003, the entire contents of which are incorporated herein by reference.

### BACKGROUND OF THE INVENTION

1. Field of the Invention

The present invention relates to a semiconductor device and a method of manufacturing the semiconductor device, and in particular, to a trench capacitor in a semiconductor memory device such as a DRAM and a method of manufacturing the same.

2. Description of the Related Art

As is well known, in a trench capacitor of a trench type DRAM such as a specific-application DRAM or an embedded DRAM, an oxide film is formed on a sidewall of an upper end of the trench in order to prevent a leakage current from a cell transistor at the upper end of the trench to an accumulated electrode area extending from a central portion to a lower end of the trench. Normally, the oxide film is formed by a thermal oxidation at a high temperature and a chemical vapor deposition.

Specifically, the trench capacitor is produced by a manufacturing process as shown in FIGS. 7 to 12.

As shown in FIG. 7, a silicon oxide film 32 and a silicon nitride film 33 are sequentially formed on a surface of, for example, a P-type semiconductor substrate 31 having a well. Then, a lithography technique and anisotropic etching are used to form openings 34 in the silicon nitride film 33.

The silicon nitride film 33 having the openings 34 is used as a mask to form a pair of deep trenches 35 in the semiconductor substrate 31. After a capacitor insulating film 36 is formed on an exposed inner wall, a first doped polysilicon 37 is buried in each of the trenches 35. Subsequently, the capacitor insulating film 36 and the polysilicon 37 are removed down to a desired first depth using anisotropic or isotropic etching.

As shown in FIG. 8, a silicon oxide film 38 is formed on the exposed trench inner wall. Further, a thick oxide film 39 such as a silicon oxide film is formed over the silicon oxide film 38 and the substrate surface using a chemical vapor deposition technique. Such a stacked structure composed of the silicon oxide film 38 and the oxide film 39 formed by the chemical vapor process is provided to suppress unwanted generation of a vertical parasitic transistor. Further, the silicon oxide film 38 is formed at a high temperature equal to or higher than 800° C. in order to improve a leak resistance in the vertical direction.

As shown in FIG. 9, the oxide film 39 is removed from only the bottom of each trench 35 by anisotropic etching to expose a surface of the buried polysilicon 37. Then, a second doped polysilicon 40 is buried in each of the trenches 35. Subsequently, the polysilicon 40, the oxide film 39, and the silicon oxide film 38 are etched back down to a desired second depth using anisotropic or isotropic etching.

As shown in FIG. 10, a third doped polysilicon 41 is buried in each of the trenches 35, and is etched back down to a desired third depth.

As shown in FIG. 11, the lithography technique and anisotropic etching are used to carry out STI (Shallow Trench Isolation) for element isolation to form a groove 42 that is across a pair of trench capacitors DT1 and DT2.

As shown in FIG. 12, a silicon oxide film is buried in the groove 42 and is etched back down to a desired depth to form a buried silicon oxide film 43. Then, the silicon nitride film 33, used as the mask, is peeled off. Ion implantation for adjusting a threshold value and activation annealing are then carried out. After the silicon oxide film 32 is removed from the substrate surface, a gate electrode G1 composed of a doped polysilicon film 45 and a metal silicide or salicide film 46 is formed via a gate insulating film 44. A sidewall insulating film 47 consisting of a silicon nitride film is formed on each gate electrode. Thereafter, source and drain regions 48 and 49 are formed. For example, ions of N-type impurity are implanted and contact plugs are provided using a polysilicon or the like.

In the above conventional example, as shown in FIG. 8, after the first polysilicon silicon 37 has been buried and etched back, the stacked structure composed of the silicon oxide film 38 and the oxide film 39 formed by the chemical vapor deposition is provided at the exposed trench inner wall and the trench is filled with the second polysilicon 40

In this case, Jpn. Pat. Appln. KOKAI Publication No. 2000-294747 discloses the formation of a three-layer structure of an oxide film/TEOS or silicon oxide film/nitride film as a stacked structure.

In any case, the conventional example is one process which suppresses the generation of the vertical parasitic transistor and which requires the high temperature for forming the oxide film at the upper end of the trench. This high-temperature process may cause the impurity to be diffused out of the doped polysilicon, thus reducing the impurity concentration therein. Further, the impurity may be diffused into the substrate.

### BRIEF SUMMARY OF THE INVENTION

According to a first aspect of the present invention, a trench capacitor comprises a semiconductor substrate; a trench provided in the semiconductor substrate; a first doped polysilicon filled in the trench at a lower end of the trench via a first dielectric film; and a second doped polysilicon filled in the trench at an upper end of the trench via a second dielectric film, the second doped polysilicon being contiguously disposed to the first doped polycrystal silicon, wherein the second dielectric film consists of an oxide film using radicals.

According to a second aspect of the present invention, a method of manufacturing a trench capacitor comprises forming a trench in a semiconductor substrate; forming a first dielectric film on an inner wall of the trench; filling a first doped polysilicon in the trench; removing the first doped polysilicon and the first dielectric film down to a first depth to expose an inner wall of an upper end of the trench; forming a second dielectric film on the inner wall of the upper end of the trench, the second dielectric film consisting of an oxide film formed by oxidation using radicals; selectively removing the second dielectric film from a bottom of the trench to expose the first doped polysilicon; and filling a second doped polysilicon in the trench.

### BRIEF DESCRIPTION OF THE DRAWINGS

FIGS. 1 to 4 are sectional views showing a part of a process of manufacturing a trench capacitor according to an embodiment;

FIG. 5 is a sectional view showing a part of a cell transistor including the trench capacitor according to the embodiment;

FIG. 6 is a plan view showing a part of the cell transistor including the trench capacitor according to the embodiment; and

FIGS. 7 to 12 are sectional views showing a part of a process of manufacturing a trench capacitor according to the prior art.

### DETAILED DESCRIPTION OF THE EMBODIMENT

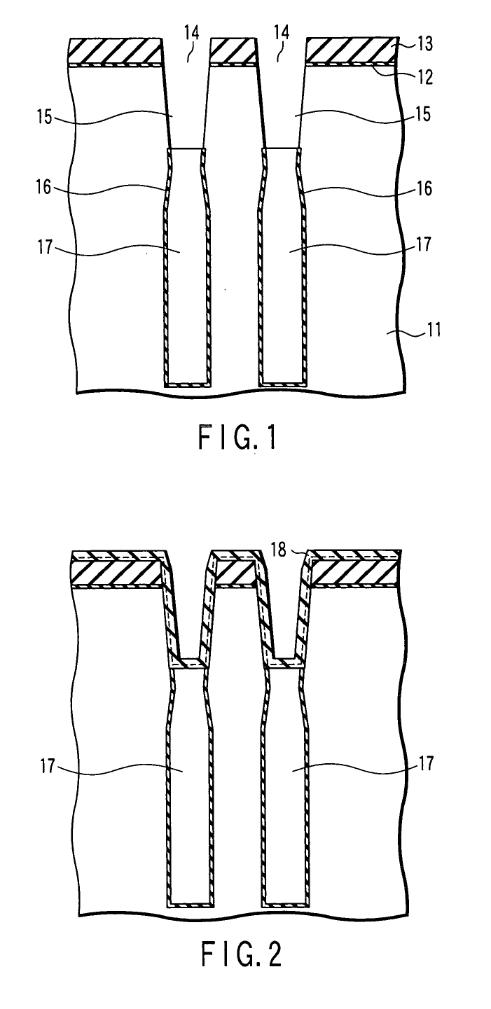

An embodiment will be described below with reference to FIGS. 1 to 6. As shown in FIG. 1, a silicon oxide film 12 and a silicon nitride film 13 are sequentially formed on a surface of, for example, a P-type semiconductor substrate 11 having a well. Then, a lithography technique and anisotropic etching are used to form openings 14 in the silicon nitride film 13.

The silicon nitride film 13 having the openings 14 is used as a mask to form a pair of deep trenches 15 in the semiconductor substrate 11. A capacitor insulating film 16, for example, a silicon oxide film, which is a first dielectric film, is formed on an exposed inner wall of each trench. Then, a first polysilicon 17 in which an impurity such as arsenic is doped is buried in each of the trenches 15. Subsequently, the capacitor insulating film 16 and the polysilicon 17 are removed down to a desired first depth using anisotropic or isotropic etching.

As shown in FIG. 2, a silicon oxide film 18 that is a second dielectric film is formed over the exposed trench inner wall and the substrate surface. The silicon oxide film 18 is formed by oxidation using radicals, that is, excited oxygen atoms/oxygen molecules or ionized oxygen atoms. The silicon oxide film 18 is formed to a thickness of 5 to 70 nm at a low temperature of 200 to 700° C. In this case, an oxide film formed by a chemical vapor deposition using the radicals can be deposited on the silicon oxide film 18 to a total thickness of 5 to 70 nm.

In normal high-temperature oxidation, activation energy that cuts Si—Si groups for oxidation is applied by heat. On the other hand, a radical state is more unstable and has higher internal energy than a normal state. When this differential energy exceeds the activation energy, low-temperature radical oxidation will occur.

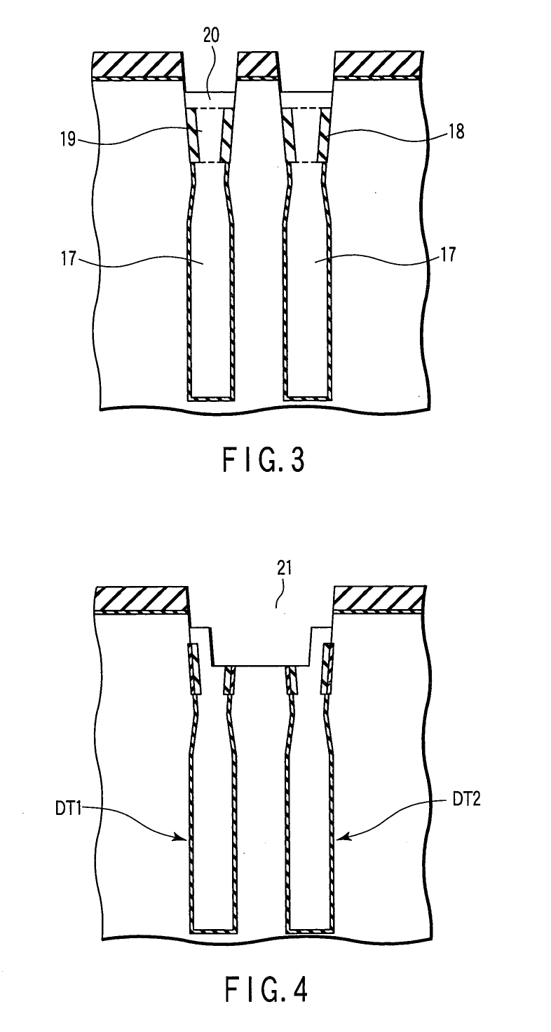

As shown in FIG. 3, the silicon oxide film 18 is removed from only the bottom of each trench 15 by anisotropic etching to expose a surface of the buried polycrystal silicon 17. Then, a second polycrystal silicon 19 in which an impurity such as arsenic are doped is buried in each of the trenches 15. Then, the polycrystal silicon 19 and the silicon oxide film 18 are etched back down to a desired second depth using anisotropic or isotropic etching.

Thereafter, a third polysilicon 20 in which the impurity such as arsenic are doped is buried in each of the trenches 15, and etched back down to a desired third depth. Also in this process, the silicon oxide film 18 is removed together with the polysilicon 19 to expose an upper end of the trench sidewall.

As shown in FIG. 4, the lithography technique and anisotropic etching are used to carry out STI processing for the isolation to form a groove 21 that is across a pair of trench capacitors DT1 and DT2.

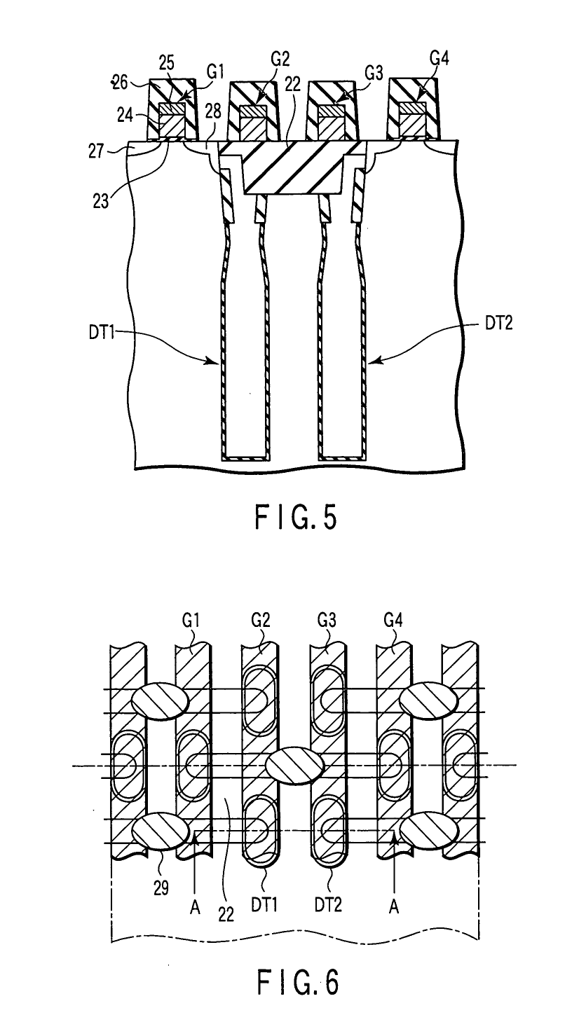

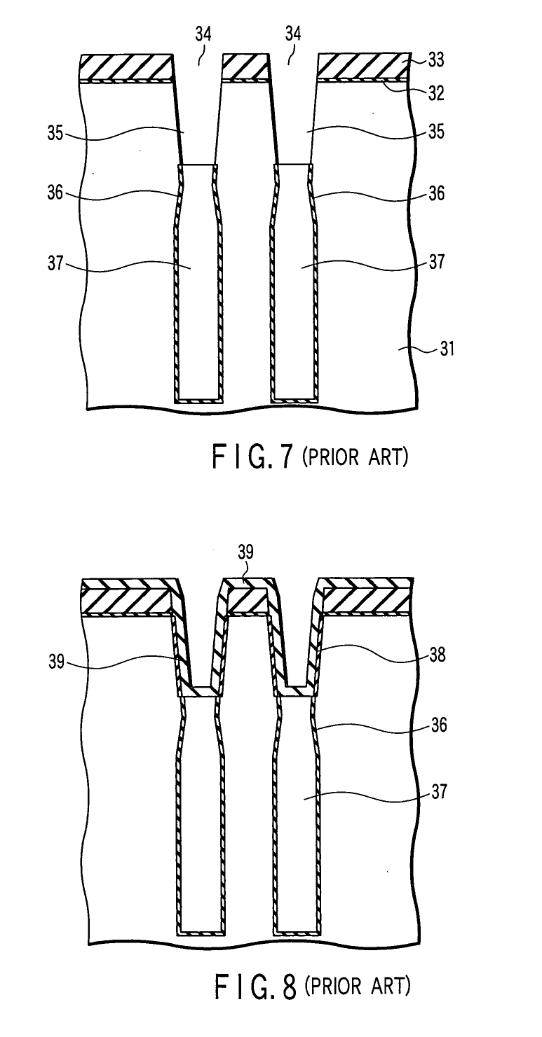

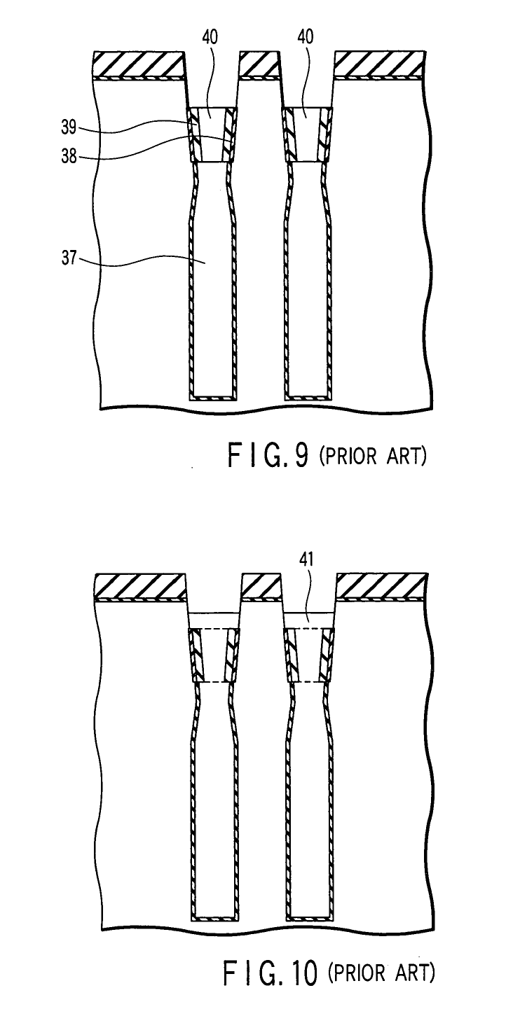

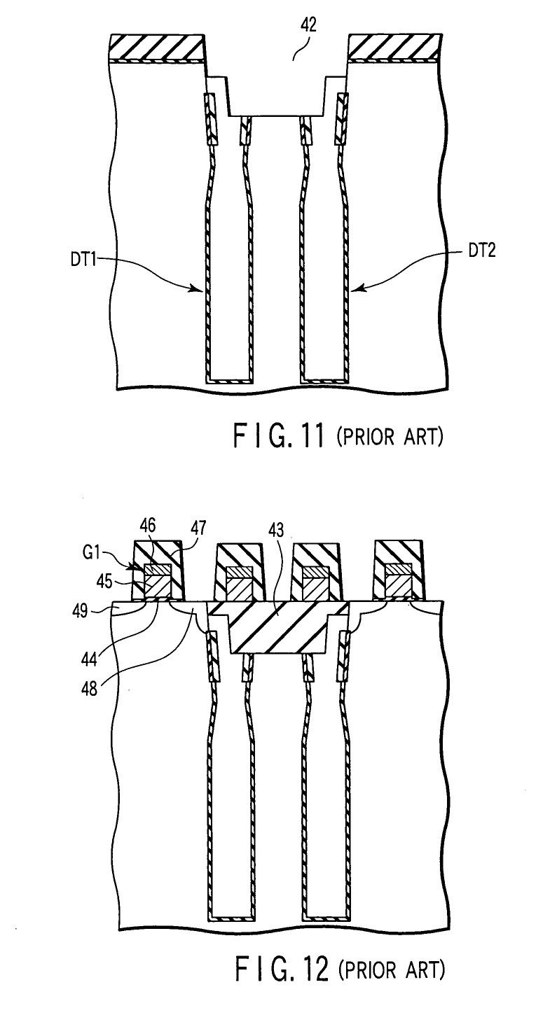

As shown in FIG. 5, a silicon oxide film is buried in the groove 21 and etched back down to a desired depth to form a buried silicon oxide film 22. Thereafter, the silicon nitride film 13, used as the mask, is peeled off. Ion implantation for adjusting the threshold value and activation annealing are then accomplished. After the silicon oxide film 12 is removed from the substrate surface, a gate electrode G1 composed of a doped polysilicon film 24 and a metal silicide or salicide film 25 is formed through a gate insulating film 23. A sidewall insulating film 26 comprised of a silicon nitride film is formed on each gate electrode. Thereafter, source and drain regions 27 and 28 are formed. For example, ions of N-type impurity are implanted and contact plugs are provided using polysilicon or the like. On this occasion, as is known, the source or drain region and the polysilicon layer in the trench capacitor are connected together through a strap region.

FIG. 6 is a plan view of a semiconductor memory device having the deep trench capacitors. FIG. 5 is a sectional view taken along a line A-A in FIG. 6. N+ source and drain regions 27 and 28 are formed in connection with the gate electrode G1. A bit line contact 29 is provided on the source region 27. Gate electrodes G2 to G4 are sequentially arranged adjacent to the gate electrode G1. N+ source and drain regions are also provided in connection with the gate electrode G4. FIG. 5 shows two cell transistors.

As is apparent from the above embodiment, the thermal process can be suppressed by using the radicals to form the oxide film at the low temperature which inhibits the generation of the parasitic transistor at the upper end of the trench capacitor. This will suppress the unwanted out diffusion of impurity from the polysilicon to prevent a decrease in the concentration of impurity in the polysilicon. Further, the impurity diffusion in the substrate will be

1. A trench capacitor comprising:
a semiconductor substrate;
a trench provided in the semiconductor substrate;
a first doped polysilicon filled in the trench at a lower end of the trench via a first dielectric film; and
a second doped polysilicon filled in the trench at an upper end of the trench via a second dielectric film, the second doped polysilicon being contiguously disposed to the first doped polycrystal silicon,
wherein the second dielectric film consists of an oxide film using radicals.

2. The trench capacitor according to claim 1, wherein the second dielectric film has a thickness of 5 to 70 nm.

3. The trench capacitor according to claim 1, wherein the radicals consist of excited oxygen atoms/oxygen molecules or ionized oxygen atoms.

4. A method of manufacturing a trench capacitor, the method comprising:
forming a trench in a semiconductor substrate;
forming a first dielectric film on an inner wall of the trench;
filling a first doped polysilicon in the trench;
removing the first doped polysilicon and the first dielectric film down to a first depth to expose an inner wall of an upper end of the trench;
forming a second dielectric film on the inner wall of the upper end of the trench, the second dielectric film consisting of an oxide film formed by oxidation using radicals;
selectively removing the second dielectric film from a bottom of the trench to expose the first doped polysilicon; and
filling a second doped polycrystal silicon in the trench.

5. The method according to claim 4, wherein the radicals consist of excited oxygen atoms/oxygen molecules or ionized oxygen atoms.

6. The method according to claim 4, wherein the oxidation using the radicals are carried out at a temperature of 200 to 700° C.

7. The method according to claim 4, wherein an oxide film formed by a chemical vapor process is further deposited on the second dielectric film.

8. The method according to claim 4, wherein the second dielectric film is formed to a thickness of 5 to 70 nm.

9. The method according to claim 7, wherein a total film thickness is formed to a thickness of 5 to 70 nm.
